(19) United States
(12) Patent Application Publication
(10) Pub. No.: US 2008/0206968 A1
(43) Pub. Date: Aug. 28, 2008

(54) Manufacturing method of semiconductor device

(75) Inventor: Unryu Ogawa, Toyama-shi (JP)

Correspondence Address: OLIFF & BERRIDGE, PLC, P.O. BOX 320850, ALEXANDRIA, VA, 22320-4850, US

(73) Assignee: HITACHI KOKUSAI ELECTRIC INC., TOKYO (JP)

(21) Appl. No.: 11/987,893

(22) Filed: Dec. 5, 2007

(30) Foreign Application Priority Data
Dec. 27, 2006 (JP) 2006-353016
Nov. 16, 2007 (JP) 2007-298553

(51) Int. Cl. H01L 21/203

(52) U.S. Cl. 438/486; 257/E21.094

(57) ABSTRACT

To create a laminated film of a silicon oxide film and a silicon nitride film, with large current driving force and large dielectric constant. A manufacturing method of a semiconductor device includes: forming an amorphous silicon film on the silicon oxide film; and forming a single crystal silicon film by annealing the amorphous silicon film.

### BACKGROUND

1. Technical Field

The present invention relates to a manufacturing method of a semiconductor device for forming a laminate film of a silicon oxide film and a silicon nitride film, and particularly relates to a forming technique of a gate insulating film such as logic, DRAM, and nonvolatile memory.

2. Background Art

Conventionally, the gate insulating film of the nonvolatile memory (such as a flush memory) has, for example, a laminate film of a silicon oxide film and a silicon nitride film. In the manufacturing method of this laminate film, after the silicon oxide film is formed on the surface of a silicon substrate, this silicon oxide film is nitrided by nitrogen plasma and a silicon nitride film is formed thereon (for example, see patent document 1).

Thus, conventionally, after the silicon oxide film is formed, a dielectric constant of the gate insulating film is raised by using a method of nitriding the silicon oxide film by nitrogen plasma. In addition, a leak current of a film is reduced by increasing a physical film thickness of the gate insulating film and a reliability of a device is improved. [Patent document 1] Japanese Patent Laid Open No. 2004-47950

However, there are the following problems in a conventional technique for forming the silicon nitride film by nitriding the silicon oxide film as described above.

In order to increase capacity of the gate insulating film, the silicon oxide film must be made thin. However, when the silicon oxide film is made thin, an amount of nitrogen diffused as far as an interface between silicon and the silicon oxide film is increased, thus involving a problem that a current driving force of charged particles flowing through an interface layer is reduced.

In addition, when the silicon oxide film is nitrided, the oxynitride silicon film is formed. Therefore, nitrogen concentration in the nitride film is decreased, thus involving a problem that no large value as expected can be obtained as the dielectric constant of the gate insulating film.

A subject of the present invention is to provide the manufacturing method capable of easily manufacturing the semiconductor device with large current driving force and large dielectric constant.

### SUMMARY OF THE INVENTION

In order to solve the above-described problems, an object of the present invention is to provide a manufacturing method of a semiconductor device including: forming an amorphous silicon film on a silicon oxide film, and forming a single crystal silicon film by annealing the aforementioned amorphous silicon film.

According to the present invention, when a silicon nitride film is formed from the single crystal silicon film, it is possible to easily manufacture the semiconductor device having a large current driving force and a large dielectric constant, compared to a case that the silicon nitride film is formed from the silicon oxide film.

### BRIEF DESCRIPTION OF THE DRAWINGS

FIG. 1 is an explanatory view showing a manufacturing step of a gate insulating film according to an embodiment of the present invention.

FIG. 2 is a schematic sectional view of a semiconductor device according to an embodiment of the present invention.

FIG. 3 is a schematic sectional view of the semiconductor device including the gate insulating film according to an embodiment of the present invention.

FIG. 4 is a schematic block diagram of an MMT apparatus showing an embodiment of the present invention.

FIG. 5 is a schematic block diagram showing an example of a vertical apparatus.

FIG. 6 is a schematic block diagram showing an example of a single wafer processing apparatus.

### DESCRIPTION OF PREFERRED EMBODIMENTS OF THE INVENTION

Explanation will be given hereunder to an embodiment of forming the silicon nitride film on a wafer, as one step of a manufacturing method of the semiconductor device. A method for forming the silicon nitride film includes: a first step of forming an amorphous silicon film and a single crystal silicon film and a second step of forming the silicon nitride film.

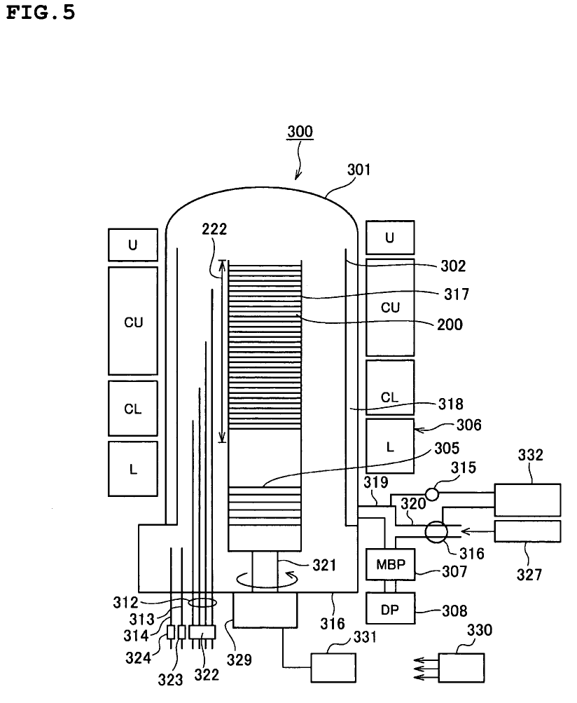

First, explanation is given to an apparatus that forms the amorphous silicon film and the single crystal silicon film in the first step, by using FIG. 5. FIG. 5 shows a structure of a reaction furnace of a hot-wall type reduced pressure vertical apparatus.

An outer tube 301 made of quartz, being an outer cylinder of a reaction furnace 300, and an inner tube 302 inside of the outer tube 301 are set inside of a hot-wall constituted of a heater 306 which is divided into four zones such as U, CU, CL, and L.

A lower end opening of the outer tube 301 and the inner tube 302 is sealed by a stainless seal cap 316. A gas supply pipe constituted of a plurality of nozzles is formed in this seal cap 316 so as to penetrate therethrough. The gas supply pipe is constituted of a nozzle 312 for supplying gas such as mono silane, a nozzle 313 for supplying the other gas, and a nozzle 314 for supplying boron trichloride gas. A processing gas is supplied into the inner tube 302 by these nozzles 312, 313, 314. Note that the boron trichloride gas is supplied for boron doping, to make a gate electrode for DRAM, for example, have conductivity. In addition, the nozzle 312 is constituted of a plurality of nozzle parts having different lengths, and is also called a mid-flow nozzle, because the gas such as mono silane is supplied from a mid-flow part in a wafer arrangement area 222 of a boat 317.

In addition, these nozzles 312, 313, and 314 of gas are connected to mass flow controllers (MFC) 322, 323, and 324, respectively, so that a flow rate of the supplied gas can be controlled to be a prescribed amount. Note that one MFC 322 of the nozzle 312 constituted of a plurality of nozzle parts is formed in FIG. 5, for convenience. However, actually, a plurality of MFCs are provided for every plurality of nozzle parts.

In addition, a cylindrical space 318 formed between the outer tube 301 and the inner tube 302 is connected to an exhaust tube 319. The exhaust tube 319 is connected to a mechanical booster pump 307 and a dry pump 308, so that the gas flown through the cylindrical space 318 between the outer tube 301 and the inner tube 302 is exhausted. In addition, the exhaust tube 319 is branched at the upper stream side of the mechanical booster pump 307, and this branched exhaust tube 320 is connected to an N₂ ballast source 327 via an automatic pressure controller 326. This automatic pressure controller 326 includes, for example, APC, a valve for N2 ballast, for detecting the pressure inside of the exhaust tube 319 by a pressure gauge 315, so that a controller 332 controls the automatic pressure controller 326 by a detection value thus obtained.

In addition, the boat 317 made of quartz, into which a plurality of wafers 200 are charged, is installed in the inner tube 302. An insulating board 305 mounted on a lower part of the boat 317 is a board for insulating a part between the boat 317 and the lower part of the apparatus. This boat 317 is supported by a rotary shaft 321 air-tightly inserted from the seal cap 316. The rotary shaft 321 rotates the boat 317 and the wafer 200 held on the boat 317, so that the boat 317 is controlled by a rotating mechanism 329 so as to rotate at a prescribed speed. Further, the boat 317 is controlled so as to be freely elevated by a boat elevator 331.

Note that each structure is controlled by a controller 330.

By using the aforementioned vertical type apparatus, an amorphous silicon film and a single crystal silicon film are formed in the first step.

First, the boat 317 is lowered by the boat elevator 331. A plurality of silicon wafers 200, with a silicon oxide film formed thereon, are charged and held in the boat 317.

Subsequently, a temperature in the reaction furnace 300 is set at a prescribed processing temperature while heating the inside of the reaction furnace 300 by a heater 306.

An inert gas, with flow rate controlled by the MFC 322, is supplied into the reaction furnace 300 by the nozzle 312, and the inside of the reaction furnace 300 is filled with the inert gas in advance. The boat 317 is elevated by the boat elevator 331 and is moved into the reaction furnace 300, and an entrance of furnace is air-tightly closed by the seal cap 316. An inside temperature of the reaction furnace 300 is maintained to a prescribed processing temperature. At this time, a temperature gradient in the reaction furnace 300 formed by a heating control by the controller 330 of the heater 306 is set at flat, namely, zero. The reason for setting the temperature gradient at zero is that a film quality and a film thickness of the wafer 200, having influence on the temperature, must be made uniform.

After exhausting the inside of the reaction furnace 300 up to a prescribed vacuum state, the boat 317 and a plurality of wafers 200 held on the boat 317 are rotated by the rotary shaft 321 and the rotating mechanism 329. Simultaneously, film forming gas such as silane, with flow rate controlled by the MFC 322, is supplied into the reaction furnace 300. The supplied gas is elevated in the reaction furnace 300, and is supplied to the plurality of wafers 200 arranged in a wafer arrangement area 222. The pressure inside of the reaction furnace 300 during pressure reducing process is controlled by the automatic pressure controller 326 so as to be exhausted via the exhaust tube 319 and is set in a vacuum state, and a pressure reducing process for a prescribed time, namely, a film forming step of an amorphous silicon film is executed.

When trichloride boron gas, with flow rate controlled, is supplied into the reaction furnace 300 by the MFC 324 from the nozzle 314 after the above-described amorphous silicon film forming step, a doped amorphous silicon film containing boron on an entire surface of the amorphous silicon film can be formed.

Thus, after formation of the doped amorphous silicon film is ended, the amorphous silicon film is annealed as it is in the reaction furnace and a single crystal silicon film is thereby formed.

After the single crystal silicon film is formed, the gas in the reaction furnace 300 is replaced with the inert gas and the pressure is set to be a normal pressure. Thereafter, the boat 317 is lowered by the boat elevator 331, and the boat 317 and the already processed wafer 200 are taken out from the reaction furnace 300. The already processed wafer 200 on the boat 317 taken out from the reaction furnace 300 is carried to an apparatus for executing the next second step.

Next, the apparatus for executing a nitriding step, being the second step of the present invention, will be explained.

A plasma processing module of the present invention is a substrate processing module (called an MMT apparatus hereunder) for plasma-processing the substrate such as a wafer by using a modified magnetron typed plasma source capable of generating a high density plasma by an electric field and a magnetic field. In this MMT apparatus, the substrate is installed in the processing chamber in which air-tightness is secured, reactive gas is introduced into the processing chamber via a shower head, the inside of the processing chamber is maintained to a constant pressure, and a high frequency power is supplied to a discharge electrode to form the electric field and also form the magnetic field, to thereby cause a magnetron discharge to occur. Electrons emitted from the discharge electrode continue a cycloid movement and circulate while drifting along, thus realizing a longer operating life, thus improving ionized ratio to generate the high-density plasma. Thus, each kind of plasma processing can be applied to the substrate, including a diffusion processing such as oxidizing or nitriding the surface of the substrate by exciting and decomposing the reactive gas, or forming the thin film on the surface of the substrate, or etching the surface of the substrate.

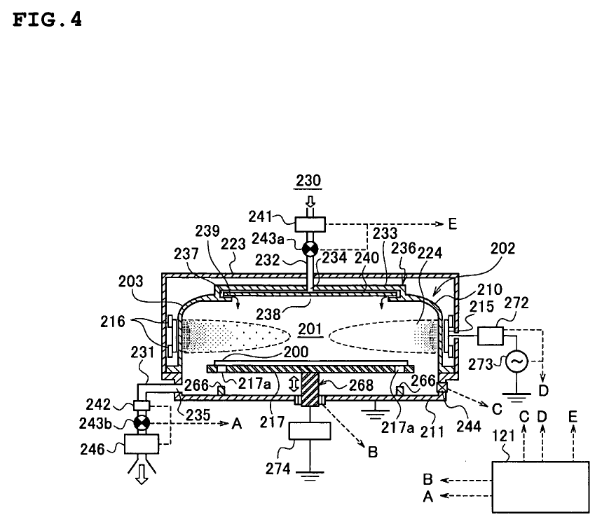

FIG. 4 shows an outline block diagram of such an MMT apparatus. The MMT apparatus has a processing vessel 203, with this processing vessel 203 formed by a dome-shaped upper side vessel 210, being a first vessel, and a bowl-shaped lower side vessel 211, being a second vessel, in which the lower side vessel is covered with the upper side vessel 210. The upper side vessel 210 is formed of non-metal material such as aluminum oxide or a non-metal material such as quartz, and the loser side vessel 211 is formed of aluminum. In addition, a susceptor 217, being a substrate holding tool (substrate holder) of a heater-integral type is constituted of nitride aluminum or the non-metal material such as ceramics or quartz, thereby reducing a metal contamination incorporated during processing.

A shower head 236 is disposed in an upper part of the processing chamber 201, including a cap-shaped lid member 233, a gas inlet port 234, a buffer chamber 237, an opening 238, a shielding plate 240, and a gas blowing port 239. The buffer chamber 237 is provided as a dispersion space for dispersing the gas introduced from the gas inlet port 234.

A gas supply tube 232 for supplying gas is connected to the gas inlet port 234, and the gas supply tube 232 is connected to a gas cylinder of a reactive gas 230 not shown via a valve 243a, being an opening/closing valve, and a mass flow controller 241, being a flow rate controller (flow rate control unit). The reactive gas 230 is supplied to the processing chamber 201 from the shower head 236, and a gas exhaust port 235 for exhausting the gas to a side wall of the lower side vessel 211 is provided, so that the gas after processing the substrate flows to a bottom direction of the processing chamber 201 from a circumference of the susceptor 217. A gas exhaust tube 231 for exhausting the gas is connected to the gas exhaust port 235, and the gas exhaust tube 231 is connected to a vacuum pump 246, being an exhaust device, via an APC 242, being a pressure adjuster, and a valve 243b, being an opening/closing valve.

A cylindrical electrode 215, being a first electrode of a tabular shape, for example, formed in a cylinder shape, is provided. The cylindrical electrode 215 is installed on an outer periphery of the processing vessel 203 (upper side vessel 210) to surround a plasma generating region 224 in the processing chamber 201. A high frequency power supply 273 for applying a high frequency power via a matching unit 272 for matching an impedance is connected to the cylindrical electrode 215.

In addition, a cylindrical magnet 216, being a magnetic field forming mechanism (magnetic field forming part) cylindrically formed, for example, formed in a cylinder shape, is a cylinder-shaped permanent magnet. The cylindrical magnet 216 is disposed near an upper/lower ends of the outer surface of the cylindrical electrode 215. The upper/lower cylindrical magnets 216, 216 have magnetic poles on both ends (inner peripheral end and outer peripheral end) along a radius direction of the processing chamber 201, and directions of the magnetic poles of the upper/lower cylindrical magnets 216, 216 are reversely set. Accordingly, the magnetic poles of the inner peripheral parts become different poles, thus forming a magnetic line in a direction of a cylinder axis along the inner peripheral surface of the cylindrical electrode 215.

A susceptor 217 is disposed in a center of a bottom side of the processing chamber 201, as a substrate holding tool (substrate holder) for holding the wafer 200, being the substrate. The susceptor 217 is formed of, for example, nitride aluminum and ceramics, or the non-metal material such as quartz, including a heater (not shown) as a heating mechanism (heating part) integrally embedded inside, so that the wafer 200 can be heated. Power is applied to the heater, so that the wafer can be heated up to about 700° C.

In addition, a second electrode, being an electrode for changing the impedance, is also equipped inside of the susceptor 218, and this second electrode is grounded via an impedance variable mechanism 274. The impedance variable mechanism 274 is constituted of a coil or a variable capacitor, and by controlling the number of patterns of the coil and a capacity of the variable capacitor, a potential of the wafer 200 can be controlled via the aforementioned electrode or the susceptor 217.

A processing module 202 for processing the wafer 200 by magnetron discharge by a magnetron type plasma source is constituted of at least the processing chamber 201, the processing vessel 203, the susceptor 217, the cylindrical electrode 215, the cylindrical magnet 216, the shower head 236, and the exhaust port 235, and the wafer 200 can be treated by plasma in the processing chamber 201.

A shielding plate 223 for effectively shielding the electric field and the magnetic field is provided around the cylindrical electrode 215 and the cylindrical magnet 216, so that an adverse influence is not applied to an external environment or other processing module by the electric field and the magnetic field formed by these cylindrical electrode 215 and the cylindrical magnet 216.

The susceptor 217 is insulated from the lower side vessel 211, and a susceptor elevating mechanism (elevator) 268 for elevating the susceptor 217 is provided. In addition, a through hole 217a is formed in the susceptor 217, and wafer push-up pins 266 for pushing up the wafer 200 are provided at three parts on the bottom surface of the lower side vessel 211. Then, the through hole 217a and the wafer push-up pins 266 are disposed, so as to be set in a positional relation in which each wafer push-up pin 266 penetrate the through hole 217a in a non-contact state with the susceptor 217, when the susceptor 217 is lowered by the susceptor elevating mechanism 268.

In addition, a gate valve 244, being a partition valve is provided on the side wall of the lower side vessel 211, and when the valve is opened, the wafer 200 is loaded or unloaded into/from the processing chamber 201 by a carrying mechanism (carrier) not shown, and when the valve is closed, the processing chamber 201 can be air-tightly closed.

In addition, a controller 121 as a control unit (control part) controls the APC 242, the valve 243b, and the vacuum pump 246 through a signal line A, controls the susceptor elevating mechanism 268 thorough a signal line B, controls the gate valve 244 thorough a signal line C, controls the matching unit 272 and the high frequency power supply 273 through a signal line D, controls the mass flow controller 241 and the valve 243a through a signal line E, and further controls the heater and the impedance variable mechanism 274 embedded in the susceptor through a signal line not shown.

Next, explanation will be given to a method of prescribed plasma processing, for example, oxidizing processing or nitriding processing applied to the surface of the wafer 200 or the surface of an underground film formed on the wafer 200, as one step of the manufacturing step of the semiconductor device, by using the processing module having the following structure. Note that in the explanation given hereunder, an operation of each part constituting the substrate processing apparatus is controlled by the controller 121.

The wafer 200 is loaded into the processing chamber 201 by a carrying mechanism not shown for carrying the wafer from outside of the processing chamber 201 constituting the processing module 202, and is carried on the susceptor 217. Details of this carrying operation are as follows. The susceptor 217 is lowered to a substrate carrying position, and a tip end of the wafer push-up pin 266 is passed through the through hole 217a. At this time, the push-up pine 266 is set in a state of being pushed-up by a prescribed height portion from the surface of the susceptor 217. Next, the gate valve 244 disposed in the lower side vessel 211 is opened and the wafer 200 is mounted on the tip end of the wafer push-up pin 266 by the carrying mechanism not shown. When the carrying mechanism is retreated to the outside of the processing chamber 201, the gate valve 244 is closed. When the susceptor 217 is elevated by the susceptor elevating mechanism 268, the wafer 200 can be mounted on the upper surface of the susceptor 217, and further the susceptor is elevated to the position where the wafer 200 is processed.

The heater embedded in the susceptor 217 is previously heated, and the loaded wafer 200 is heated to a prescribed wafer processing temperature, in a range from a room temperature to 700° C. The pressure in the processing chamber 201 is maintained to a prescribed pressure in a range from 0.1 to 100 Pa by using a vacuum pump 246 and an APC 242.

When the temperature of the wafer 200 reaches a prescribed temperature and stabilized, the reactive gas, for example oxygen O₂ or nitrogen N₂ are introduced toward the upper surface (processing surface) of the wafer 200 disposed in the processing chamber 201, from the gas inlet port 234 via the gas blowing port 239 of the shielding plate 240. The gas flow rate at this time is set at a prescribed flow rate in a range from 10 to 5000 sccm. Simultaneously, the high frequency power is applied to the cylindrical electrode 215 from the high frequency power supply 273 via the matching unit 272. As an applied power, a prescribe output value in a range from 150 to 2000 W is applied. The impedance variable mechanism 274 at this time is controlled so that a desired impedance value can be obtained in advance.

The magnetron discharge is generated under an influence of the magnetic field of the cylindrical magnets 216, 216, charges are trapped in an upper space of the wafer 200, and the high density plasma is generated in the plasma generating region 224. Then, by the high density plasma thus generated, plasma processing is applied to the surface of the wafer 200 on the susceptor 217. The wafer 200 that has undergone the plasma processing is carried outside of the processing chamber 201 by a reverse procedure to the procedure for loading the substrate, by using the carrying mechanism not shown.

Here, the manufacturing method of the semiconductor device will be explained.

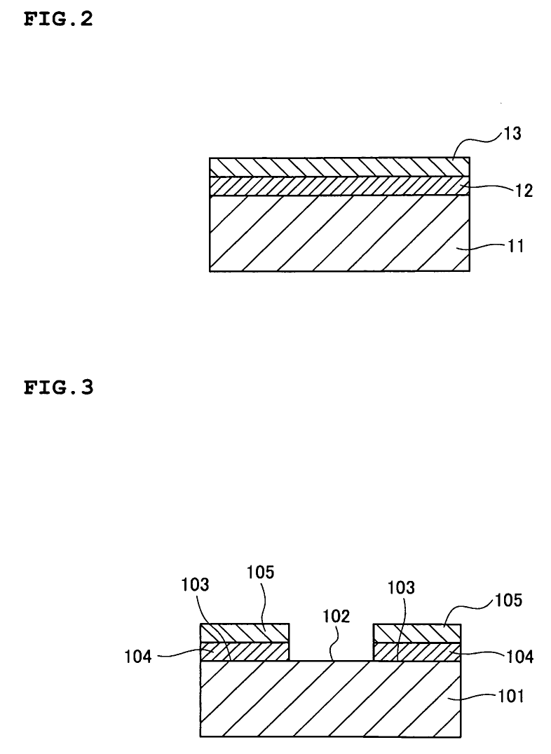

FIG. 2 is an outline sectional view illustrating an example of the semiconductor device including a gate insulating film. The semiconductor device includes a device such as a logic, a DRAM, and a nonvolatile memory. The gate insulating film is constituted of a laminated film of a silicon oxide film 12 as an underground silicon film formed on a substrate 11 and a silicon nitride film 13 formed on a silicon oxide film 12.

The gate insulating film of the semiconductor device may be the gate insulating film of a flush memory formed on a semiconductor silicon substrate as the substrate, depending on the embodiment.

FIG. 3 is an outline sectional view illustrating an example of the gate insulating film of the flush memory. The gate insulating film is an oxide film formed on a silicon substrate 101, and a part of the gate insulating film formed on a non-gate region surface 102 out of the gate insulating film formed on an entire surface of the silicon substrate 101 is removed, and other part of the gate insulating film formed on a gate region surface 103 is constituted of a silicon oxide film 104 and a silicon nitride film 105 formed on the silicon oxide film 104. This silicon oxide film 105 is formed, for example, by annealing an amorphous silicon film formed on an entire surface of the silicon substrate 101, thereby performing single crystallization of silicon, and plasma-nitriding this single crystal silicon film.

The apparatus used in the first step of the aforementioned embodiment is used when the amorphous silicon film is formed or when the amorphous silicon film is subjected to annealing for performing silicon single-crystallization. In addition, the MMT apparatus is suitably used in a case that the single crystal silicon film is subjected to plasma-nitriding process.

A creating method of the gate insulating film of the flush memory as shown in FIG. 3 includes:

forming the single crystal silicon film on the silicon oxide film 104 as an underground silicon film; and

forming the silicon nitride film 105 by nitriding the single crystal silicon film.

SiN, Si₃N₄, Si_{X}N_{V} are given as examples of the silicon nitride film 105 formed here, and generally, the composition of the CVD film at a high temperature and a thermally nitrided silicon nitride film is expressed by Si₃N₄. The silicon nitride film 105 is called a Si₃N₄ film 105 hereunder. In addition, the silicon oxide film 104 is called a SiO₂ film 104 hereunder.

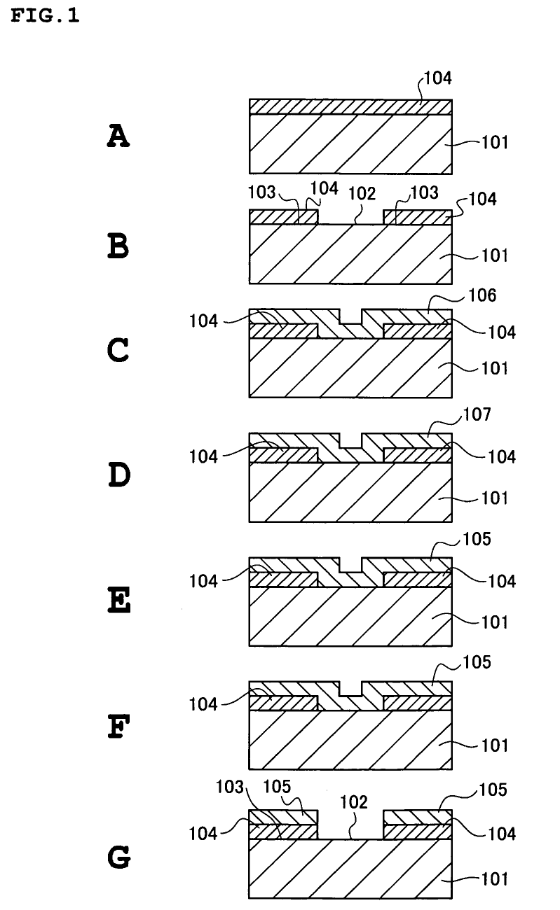

Next, the creating method of a specific gate insulating film will be explained by using FIG. 1.

Step 1 (Oxidation (FIG. 1(a))

In order to form the SiO₂ film 104, being the underground silicon film, the surface of the silicon substrate 101 is oxidized to form the SiO₂ film. Specifically, a thin SiO₂ film 104 is formed on the surface of the silicon substrate 101 by activating the gas containing oxygen by plasma, or by thermal oxidation by heat. For example, the thin SiO₂ film has a thickness from 0.6 nm to 3.0 nm.

In order to form the SiO₂ film by activating the gas containing oxygen by plasma, for example, the aforementioned MMT apparatus and the CVD apparatus are used. For example, O₂, O₂+H₂, H₂O, etc is used as the gas containing oxygen. In a case of the MMT apparatus, when the impedance variable mechanism 274 installed between the susceptor 217 and earth is previously adjusted to obtain a desired impedance value, for oxidizing the surface of the silicon substrate 101, the potential of the wafer 200 is thereby controlled, and the SiO₂ film 104 having a film thickness in the aforementioned range and uniformity of in-surface film thickness can be formed.

The step of forming a single crystal silicon film 107 on the SiO₂ film 104, being the aforementioned underground silicon film specifically includes the steps from step 2 to step 4.

Step 2 (Removal of a Part of the Oxide Film (FIG. 1(b))

A part of the SiO₂ film is removed to expose the surface of the silicon substrate 101. Specifically, by allowing the SiO₂ film 104 on the gate region surface 103 to be remained and removing the SiO₂ film on the non-gate region surface 102, single crystal silicon of the silicon substrate 101 is exposed on the non-gate region surface 102. Wet etching or dry etching by plasma is used for the means for removing a part of the SiO₂ film on the surface of the silicon substrate 11. The dry etching by plasma is executed by using the aforementioned MMT apparatus or the existing etching apparatus. In this case, for example, NF₃, CIF₃ are used as etching gas.

Step 3 (Formation of the Amorphous Silicon Film (FIG. 1(c))

An amorphous silicon film 106 is formed on an entire surface of the silicon substrate 101 including the exposed single crystal silicon surface. In order to form the amorphous silicon film 106, specifically, the apparatus used in the aforementioned first step, namely, an epitaxial apparatus is used. In this case, for example, Si₂H₆ and SiH₄, etc, are used as a source gas.

At this time, the pressure is set at 100 Pa, a substrate temperature is set at 500° C., and a processing time is set at about 10 minutes.

Step 4 (Annealing (FIG. 1(d))

After the amorphous silicon film 106 is formed, annealing process is performed in the same processing chamber, and the single crystal silicon film 107 is formed. Specifically, annealing is performed at a temperature of the substrate set at not less than 500° C. and not more than 650° C. Particularly preferably, the annealing is performed at a temperature of 550° C. or more. By this annealing process, the silicon of an amorphous structure is single crystal. The annealing is performed in a nitrogen atmosphere.

The pressure at this time is set at a normal pressure and the processing time is set at 10 hours or more.

Next, the step of nitriding the single crystal silicon film 107 and forming the Si₃N₄ film 105 includes the step 5 and the step 6.

Step 5 (Nitrization (FIG. 1(e))

The single crystal silicon film 107 is nitrided to form the Si₃N₄ film 1-5. Preferably, the step of nitriding the single crystal silicon film 107 and forming the Si₃N₄ film 105 is the step of forming the single crystal silicon film 107 by nitriding process.

In the nitriding process, for example, the aforementioned MMT apparatus is used. In order to apply nitriding process to the single crystal silicon film 107, the gas containing nitrogen N₂ is supplied toward the upper surface (processing surface) of the wafer 200 in the processing chamber 201 like shower, with the temperature of the silicon substrate 101 maintained in a range from a room temperature (25° C.) to 700° C., and the pressure in the processing chamber maintained in a range from 0.1 Pa to 100 Pa. The gas flow rate at this time is in a range from 10 to 5000 sccm. Simultaneously, a power output value in a range from 150 to 2000 W is applied to the cylindrical electrode 215 via the matching unit 272 from the high frequency power supply 273. The high density plasma is generated in the plasma generating region 224, and the surface of the wafer 200 on the susceptor 217 is subjected to plasma nitriding process. As the gas containing nitrogen N₂, for example, N₂, NO, N₂O, NH₃, H₂H₆, etc, are used.

Dilution gas such as He and Ar may be added to the aforementioned nitrogen containing gas. This is because nitrization is accelerated by a catalytic action of a dilution gas. The catalytic action here means the action of making He, being the dilution gas, into plasma at the time of making a nitrogen component into plasma, and by the dilution gas made into plasma, energy is given to the nitrogen component.

When the impedance variable mechanism 274 installed between the susceptor 217 and earth is adjusted to obtain a desired impedance value in advance at the time of performing the nitriding process, the potential of the wafer 200 is thereby controlled to form a nitride processed film having a desired film thickness and uniformity of in-surface film thickness can be formed. Here, the desired thickness of the Si₃N₄ film is in a range from 0.3 nm to 5.0 nm.

Although depending on the film thickness, the processing time at this time is set at 5 seconds or more and 10 minutes or less. In addition, when the processing substrate temperature is set at about 600° C., a more preferable film quality can be obtained.

Step 6 (Annealing (FIG. 1(f))

The Si₃N₄ film 105 is annealed and stabilized. As the annealing, for example, NO annealing is executed at a temperature of 800° C. or more in an NO atmosphere. The annealing is executed by using the aforementioned MMT apparatus.

The processing time at this time is set at 1 minute or more and 30 minutes or less, depending on a film pressure. Pressure reduction needs not necessarily be performed. The substrate temperature during processing is preferably set at 750° C. or more.

Such an annealing processing may be performed not only by the aforementioned MMT apparatus but also by the existent annealing apparatus such as a vertical type apparatus.

Step 7 (Partial Removal (FIG. 1(g))

The underground single crystal silicon surface is exposed by removing a part of the Si₃N₄ film 105. Specifically, the Si₃N₄ film 105 on the SiO₂ film 104 on the gate region surface 103 is remained, and by removing a part of the Si₃N₄ film of an unnecessary part on the non-gate region surface 102, the single crystal silicon is exposed on the non-gate region surface 102. Thus, a laminated of the silicon oxide film 104 and the Si₃N₄ film 105 is formed.

In order to form a gate on the gate region surface 103 after the Si₃N₄ film 105 is partially removed, further various film formations are performed on the aforementioned laminated film. For example, when the gate is the gate of the flush memory, floating gate silicon is formed on the Si₃N₄ film 105, and the SiO₂ film is formed on the upper surface and the side surface thereof. The Si₃N₄ film containing the SiO₂ film and the insulating film of ONO structure composed of the SiO₂ film are formed on this SiO₂ film. Control gate polysilicon is formed on the insulating film of the ONO structure.

As described above, in a gate insulating film forming method according to this embodiment, the silicon single crystal film is formed particularly on the silicon oxide film, and this single crystal silicon film is nitrided. Therefore, the following characteristics can be given.

A fine single crystal silicon film is nitrided by nitrogen plasma, thus making it possible to increase a degree of bonding of nitrogen and as a result, the silicon nitride film of high density can be formed.

A dielectric constant of the gate insulating film can be made large because a nitrogen concentration in the nitride film is high, compared to a case of forming the silicon nitride film by nitriding the silicon oxide film, as is a conventional case.

Further, in a case of nitrogen, thermal nitrization can also be taken into consideration. However, it is apparent that plasma nitrization is advantageous in the following points.

In a case of the thermal nitrization, nitrization needs to be performed at about 1200° C. When the single crystal film is nitrided under this condition, no nitrization can be performed but nitrization with a thickness of 12 angstrom. This is because a nitride film formed on the upper part of the substrate becomes a protective film, thus making it impossible to perform nitrization of the thickness deeper than 12 angstrom as a result.

Meanwhile, when nitrization is performed by plasma, the processing can be performed at a relatively low temperature because of a high energy, and the thickness of about 50 angstrom can be nitrided.

Accordingly, by plasma-nitriding the single crystal film, a leak current from the gate electrode can be further suppressed and the dielectric constant can be improved, compared to the thermal nitrization.

In addition, by increasing a physical film thickness of the gate insulating film, reliability of the gate insulating film can be improved, without deteriorating the characteristic of the semiconductor device.

In addition, since the nitrogen is trapped in the single crystal silicon film, the nitrogen concentration in the interface between the silicon oxide film and silicon can be significantly reduced. Accordingly, even if the film thickness of the silicon oxide film is small, a drive current of charged particles flown through an interface layer between silicon and the silicon oxide film can be increased, thus making it possible to largely improve the electric characteristics of the device compared to the conventional method.

In addition, since the nitrogen concentration of the nitride film is high, it is possible to effectively prevent a breakthrough phenomenon in which breakthrough of impurity boron (B) doped in the gate electrode of PMOS occurs.

Note that the step of nitriding process performed by the aforementioned embodiment and the step before or the step after this nitriding process may be continuously processed in the same processing chamber, or the processing may be performed in different processing chambers, with processing chambers provided for each processing. When the processing is performed continuously in the same processing chamber, the nitriding process can be stably performed, and the characteristics of the semiconductor device can be improved.

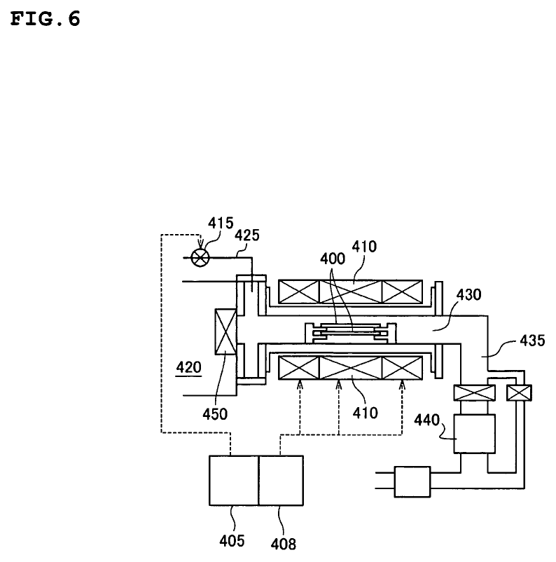

In addition, a single wafer processing apparatus shown in FIG. 6 is called a hot wall type. This device may be used instead of the batch type vertical processing apparatus, in the aforementioned amorphous silicon forming step.

In this figure, a gas supply nozzle 425 is disposed in a reaction chamber 430 connected to a carrying chamber 420 via a gate valve 450. The reaction chamber 430 is set in an ultra high-vacuum state by flowing the gas from a single direction and sucking this gas by a turbo-molecular pump 440 via an exhaust piping 435 disposed in a direction opposite to a gas supply nozzle 425 with respect to the wafer 400. A flow control valve 415 is formed in a piping that leads to the gas supply nozzle 425, and this flow control valve 415 is controlled by a flow controller 405 so that gas flow rate supplied into the reaction chamber 430 becomes a prescribed flow rate. The reaction chamber 430 has a division type resistance heating heater 410 of a counter-type to the surface of the wafer 400. Front and back both surfaces of the wafer 400 are heated by this division type heating heater 410. The division type resistance heater 410 has a temperature controller 408 for controlling the temperature in the reaction chamber 430 within a prescribed temperature range.

Next, explanation will be given to an example of a pressure reducing method by the single wafer processing apparatus having the aforementioned structure. First, the gate valve 450 is opened and the wafer 400 is inserted into the reaction chamber 430 so as to be maintained horizontally. After maintaining the wafer 400 horizontally, the gate valve 450 is closed and the inside of the reaction chamber 430 is heated by the division type resistance heating heater 410 to increase the temperature inside, so as to be maintained in a prescribed temperature. In addition, the inside of the reaction chamber 430 is exhausted to a prescribed vacuum state. After thus exhausted, the gas for processing, such as monosilane gas (SiH₄) is exhausted from the exhaust piping 435 while supplying this gas, thereby performing pressure reduction processing for a prescribed time. Thus, the amorphous silicon film is formed on the wafer 400.

Preferred aspects of the present invention will be explained additionally.

According to additional description 1, a manufacturing method of a semiconductor device is provided, including:

forming a single crystal silicon film on a silicon oxide film; and

forming a silicon nitride film by nitriding the single crystal silicon film.

Preferably, the step of forming the single crystal silicon film on the silicon oxide film includes: forming the silicon oxide film by oxidizing the surface of a silicon substrate; exposing the surface of the single crystal silicon by removing a part of the silicon oxide film; forming an amorphous silicon film on an entire surface of the silicon substrate including the exposed surface of the single crystal silicon; annealing the amorphous silicon film and forming the single crystal silicon film.

Also preferably, the step of forming the silicon oxide film by oxidizing the surface of the silicon substrate is the step of forming the silicon oxide film on the surface of the silicon substrate by activating gas containing oxygen by plasma. In addition, preferably, the step of forming the silicon nitride film by nitriding the single crystal silicon film is the step of forming the silicon nitride film by activating the gas containing nitrogen by plasma.

According to additional description 2, a manufacturing method of a semiconductor device is provided, including:

forming an amorphous silicon film on a silicon oxide film; and annealing the amorphous silicon film and forming the single crystal silicon film.

By the processing described above, a fine single crystal film can be formed on the silicon substrate.

According to additional description 3, a manufacturing method of a semiconductor device is provided, further including after processing of additional description 2: forming a silicon nitride film by applying nitriding process to a single crystal silicon film.

Since the nitriding process is applied to a fine single crystal film, the nitriding process of high bonding ratio can be applied, and as a result, a fine oxynitride film can be formed.

According to additional description 4, the manufacturing method of the semiconductor device according to the additional description 3 is provided, including: performing plasma nitriding by turning nitrogen-containing gas into plasma.

By turning the nitrogen-containing gas into plasma and nitriding the single crystal film, thus making it possible to nitride up to a distance deeper from the surface of a substrate, and as a result, a thick oxynitride film can be formed.

Thus, a leak current can be further suppressed.

According to additional description 5, the manufacturing method of the semiconductor device according to the additional description 2 is provided, wherein the step of forming the amorphous silicon film is performed by using an apparatus.

According to additional description 6, the manufacturing method of the semiconductor device according to the additional description 2 is provided, wherein the step of forming the single crystal silicon film is performed in the same processing chamber as the processing chamber used in the step of forming the amorphous silicon film.

According to additional description 7, the manufacturing method of the semiconductor device according to the additional description 2 is provided, wherein in the step of forming the single crystal silicon film, annealing is applied at a temperature of not less than 500° C. and not more than 650°.

According to additional description 8, the manufacturing method of the semiconductor device according to the additional description 3 is provided, including:

nitriding for forming a silicon nitride film by applying nitriding process to the single crystal silicon film; and

annealing the silicon nitride film formed in the nitriding process.

According to additional description 9, the manufacturing method of the semiconductor device according to the additional description 4 is provided, wherein

the nitriding process is performed by using a plasma processing apparatus;

the plasma processing apparatus has a processing chamber, a cylindrical electrode and a magnetic field forming mechanism disposed around the processing chamber, and a susceptor grounded via an impedance variable mechanism having a coil and a capacitor;

a susceptor potential is adjusted by changing an impedance of the susceptor by the coil or the capacitor of the impedance variable mechanism;

gas containing nitrogen is supplied to the processing chamber as a processing gas while applying high frequency power to the cylindrical electrode; and

a single crystal silicon film on the surface of a substrate disposed in the processing chamber is subjected to nitriding process by the gas containing plasma-excited nitrogen.

According to additional description 10, the manufacturing method of the semiconductor device according to the additional description 9 is provided, wherein dilution gas is added to the gas containing the nitrogen.

According to additional description 11, the manufacturing method of the semiconductor device according to the additional description 9 is provided, wherein a film thickness of a silicon nitride film formed by applying nitriding process to the single crystal silicon film is in a range from 0.3 nm to 5.0 nm.

What is claimed is:

1. A manufacturing method of a semiconductor device, comprising:
forming an amorphous silicon film on a silicon oxide film; and
forming a single crystal silicon film by annealing said amorphous silicon film.

2. The manufacturing method of the semiconductor device according to claim 1, further comprising:
forming a silicon nitride film by applying nitriding process to said single crystal silicon film.

3. The manufacturing method of the semiconductor device according to claim 2, wherein said nitriding process further comprises:
turning nitrogen-containing gas into plasma and performing nitriding by the gas turned into plasma.

4. The manufacturing method of the semiconductor device according to claim 1, wherein the step of forming said amorphous silicon film is performed by using a CVD apparatus.

5. The manufacturing method of the semiconductor device according to claim 1, wherein the step of forming said single crystal silicon film is performed in the same processing chamber as the processing chamber used in the step of forming said amorphous silicon film.

6. The manufacturing method of the semiconductor device according to claim 1, wherein in the step of forming said single crystal silicon film, annealing is applied at a temperature of not less than 500° C. and not more than 650° C.

7. The manufacturing method of the semiconductor device according to claim 2, wherein the step of forming said silicon nitride film includes nitriding for forming a silicon nitride film by applying nitriding process to the single crystal silicon film, and annealing for annealing the silicon nitride film formed in said nitriding.

8. The manufacturing method of the semiconductor device according to claim 3, wherein
said nitriding process is performed by using a plasma processing apparatus;
the plasma processing apparatus has a processing chamber, a cylindrical electrode and a magnetic field forming mechanism disposed around the processing chamber, and a susceptor grounded via an impedance variable mechanism having a coil and a capacitor;
a susceptor potential is adjusted by changing an impedance of said susceptor by the coil or the capacitor of said impedance variable mechanism;
gas containing nitrogen is supplied to said processing chamber as a processing gas while applying high frequency power to said cylindrical electrode; and
a single crystal silicon film on the surface of a substrate disposed in the processing chamber is subjected to nitriding process by the gas containing plasma-excited nitrogen.

9. The manufacturing method of the semiconductor device according to claim 8, wherein dilution gas is added to said gas containing nitrogen.

10. The manufacturing method of the semiconductor device according to claim 8, wherein a film thickness of a silicon nitride film formed by applying nitriding process to said single crystal silicon film is in a range from 0.3 nm to 5.0 nm.
